(19) United States
(12) Patent Application Publication
(10) Pub. No.: US 2026/0349552 A1
(43) Pub. Date: Nov. 5, 2026

(54) Peripheral Input Device

(71) Applicant: Razer (ASIA-PACIFIC) PTE LTD., Singapore (SG)

(72) Inventors: Gil Jr Palma GUERRERO, Singapore (SG); Kah Yong LEE, Singapore (SG); Ann Tiong ONG, Singapore (SG); Yifeng CHEN, Singapore (SG); Wooi Liang CHIN, Singapore (SG); Alvin SIM, Singapore (SG)

(73) Assignee: Razer (ASIA-PACIFIC) PTE LTD., Singapore (SG)

(21) Appl. No.: 19/124,492

(22) PCT Filed: Dec. 8, 2022
(86) PCT No.: PCT/SG2022/050890

§ 371 Date: Apr. 25, 2025

(51) Int. Cl. G06F 3/041; G06F 3/01; G06F 3/02; G06F 3/03; G06F 3/0346

(52) U.S. Cl. CPC G06F 3/0416; G06F 3/011; G06F 3/0304; G06F 3/0202; G06F 3/0346

(57) ABSTRACT

An peripheral input device including a housing; an input button depressible relative to the housing, the input button having a resting surface for receiving a finger of a user; a touch sensing arrangement including a touch sensing element disposed at the input button to sense a presence of the finger at the resting surface of the input button; and a displacement sensing arrangement. The displacement arrangement including a first interactive part associated with the input button in a manner so as to be movable when the input button is being depressed, and a second interactive part disposed in a fixed position with respect to the housing. When the input button is being depressed, relative movement between the first interactive part and the second interactive part causes an interaction between the first interactive part and the second interactive part as a measure of detecting that the input button is being depressed.

### TECHNICAL FIELD

Various embodiments generally relate to a peripheral input device. Particularly, various embodiments generally relate to a peripheral input device for Virtual Reality (VR) applications so as to interact with the virtual world.

### BACKGROUND

Virtual Reality (VR) is a simulated experience that allows a user to immerse in a virtual world which they can see and interact with. The way of interacting with the virtual world is usually via a VR peripheral input device. Examples of VR peripheral input devices include, but not limited to, VR controllers, VR keypads, VR gloves, VR body suits, VR treadmills, VR track pads, VR joysticks, or VR motion trackers. These VR peripheral input devices generally collect data about a user's movements and/or position and/or action, and provides them as input data into the VR applications for interacting with the virtual world. The VR peripheral input devices can be used to move around, pick things up, and interact with virtual objects. The VR peripheral input devices include input buttons such as push-buttons, triggers, thumb sticks, or the like, for the user to provide inputs to the VR applications. Generally, the input button of a VR peripheral input device has functional needs that are different from an input button of a typical peripheral input device such as the conventional mouse, conventional keyboard, conventional gaming controller, or conventional gaming pad. As an example, the input button of the VR peripheral input device may be required to allow the user to provide input for picking up an object and subsequently to squeeze or throw the object using the same input button. Thus, the input button of the VR peripheral input device may be required to allow the user to provide different types of input using the same input button.

Accordingly, there is a need for a peripheral input device that allows the user to reliably and effectively provide different kinds of inputs using the same input button.

### SUMMARY

According to various embodiments, there may be provided a peripheral input device. The peripheral input device including a housing; an input button depressible relative to the housing, the input button having a resting surface for receiving a finger of a user; a touch sensing arrangement including a touch sensing element disposed at the input button to sense a presence of the finger of the user at the resting surface of the input button; and a displacement sensing arrangement. The displacement sensing arrangement including a first interactive part associated with the input button in a manner so as to be movable when the input button is being depressed, and a second interactive part disposed in a fixed position with respect to the housing. When the input button is being depressed, relative movement between the first interactive part and the second interactive part causes an interaction between the first interactive part and the second interactive part as a measure of detecting that the input button is being depressed.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments are described with reference to the following drawings, in which:

FIG. 1A shows a schematic view of a peripheral input device according to various embodiments;

FIG. 1B shows a schematic view of the peripheral input device of FIG. 1A when at least one input button is depressed according to various embodiments;

FIG. 2 shows a flow diagram of an operational process of the peripheral input device of FIG. 1A according to various embodiments;

FIG. 3A shows a cross-section of a portion of a peripheral input device according to various embodiments;

FIG. 3B shows the cross-section of the portion of the peripheral input device of FIG. 3A when at least one input button is depressed according to various embodiments;

FIG. 4A shows a cross-section of a portion of a peripheral input device according to various embodiments;

FIG. 4B shows the cross-section of the portion of the peripheral input device of FIG. 4A when at least one input button is depressed according to various embodiments;

FIG. 5A and FIG. 5B show a sequence of movements of a motion transfer sub-arrangement and a light blocking member of the peripheral input device of FIG. 4A and FIG. 4B according to various embodiments;

FIG. 6A and FIG. 6B show cut away views of FIG. 5A and FIG. 5B to further illustrate the interaction between the light blocking member and an optical sensing sub-arrangement of the peripheral input device of FIG. 4A and FIG. 4B according to various embodiments;

FIG. 7 shows a flow diagram of an operational process of the peripheral input device of FIG. 3A and FIG. 3B according to various embodiments; and

FIG. 8 shows a flow diagram of an operational process of the peripheral input device of FIG. 4A and FIG. 4B according to various embodiments.

### DETAILED DESCRIPTION

Embodiments described below in context of the apparatus are analogously valid for the respective methods, and vice versa. Furthermore, it will be understood that the embodiments described below may be combined, for example, a part of one embodiment may be combined with a part of another embodiment.

It should be understood that the terms “on”, “over”, “top”, “bottom”, “down”, “side”, “back”, “left”, “right”, “front”, “lateral”, “side”, “up”, “down” etc., when used in the following description are used for convenience and to aid understanding of relative positions or directions, and not intended to limit the orientation of any device, or structure or any part of any device or structure. In addition, the singular terms “a”, “an”, and “the” include plural references unless context clearly indicates otherwise. Similarly, the word “or” is intended to include “and” unless the context clearly indicates otherwise.

Various embodiments relate to a peripheral input device. In particular, various embodiments relate to a Virtual Reality (VR) peripheral input device. Accordingly, the peripheral input device may include, but not limited to, a VR controller, a VR keypad, a VR glove, a VR body suit, a VR treadmill, a VR track pad, a VR joystick, or a VR motion tracker. The peripheral input device may be a handheld device and/or a standalone device for providing input to a computing system. The computing system may run a VR application and the input from the peripheral input device may allow the user to interact with the virtual world generated by the VR application. According to various embodiments, the peripheral input device may include at least one input button. The at least one input button may include, but not limited to, a push-button, a trigger, a thumb stick, a directional pad, a joystick, or the like. According to various embodiments, the at least one input button of the peripheral input device may be configured to allow a user to provide at least two different kinds of input using the same input button. For example, the at least one input button of the peripheral input device may be operated to simulate grabbing or picking up an object or item in a virtual world, and the same input button of the peripheral input device may be further operated to squeeze, throw, move, pull, push, or swing the same object or item in the virtual world.

According to various embodiments, the at least one input button of the peripheral input device may be configured to be operated by touch for providing a first kind of input and be operated by depressing the at least one input button for providing a second kind of input. Accordingly, the peripheral input device may include a touch sensing mechanism (or touch sensing arrangement) and a switch/trigger mechanism (or displacement sensing arrangement) provided to the at least one input button. Hence, the at least one input button may include the touch sensing mechanism and the switch/trigger mechanism such that the user may operate the at least one input button of the peripheral input device differently to provide different kinds of input.

The following examples pertain to various embodiments.

Example 1 is an peripheral input device including:
a housing;
an input button depressible relative to the housing, the input button having a resting surface for receiving a finger of a user;
a touch sensing arrangement including a touch sensing element disposed at the input button to sense a presence of the finger of the user at the resting surface of the input button; and
a displacement sensing arrangement including
a first interactive part associated with the input button in a manner so as to be movable when the input button is being depressed, and
a second interactive part disposed in a fixed position with respect to the housing,
wherein relative movement between the first interactive part and the second interactive part when the input button is being depressed causes an interaction between the first interactive part and the second interactive part as a measure of detecting that the input button is being depressed.

In Example 2, the subject matter of Example 1 may optionally include that wherein the touch sensing arrangement may output a touch signal upon sensing the presence of the finger of the user at the resting surface of the input button, and wherein the displacement sensing arrangement may output a displacement signal upon detecting that the input button is being depressed.

In Example 3, the subject matter of Example 1 or 2 may optionally include that wherein the displacement sensing arrangement may be turned on upon the touch sensing arrangement sensing the presence of the finger of the user at the resting surface of the input button, and wherein the displacement sensing arrangement may be turned off when the touch sensing arrangement cease to sense the presence of the finger of the user at the resting surface of the input button.

In Example 4, the subject matter of any one of Examples 1 to 3 may optionally include that wherein the input button may include a button cap, wherein the resting surface of the input button may be a crown surface of the button cap, and wherein the touch sensing element of the touch sensing arrangement may be disposed at an underside surface of the button cap opposite the crown surface of the button cap.

In Example 5, the subject matter of any one of Examples 1 to 4 may optionally include that the touch sensing element may include a conductive metal plate.

In Example 6, the subject matter of any one of Examples 1 to 5 may optionally include that wherein the interaction between the first interactive part and the second interactive part of the displacement sensing arrangement may vary continuously across a range of relative movement between the first interactive part and the second interactive part in a manner so as to be capable of serving as a measurement corresponding to an amount of depression of the input button.

In Example 7, the subject matter of any one of Examples 1 to 5 may optionally include that wherein the first interactive part of the displacement sensing arrangement may include a Hall sensor coupled to the input button in a manner so as to be movable together with the input button when the input button is being depressed, wherein the second interactive part of the displacement sensing arrangement may include a magnet fixedly disposed in the housing, and wherein the interaction between the first interactive part and the second interactive part may be the Hall sensor detecting a magnetic field of the magnet during relative movement between the Hall sensor and the magnet.

In Example 8, the subject matter of Example 7 may optionally include that wherein the Hall sensor may measure an intensity of the magnetic field of the magnet, which may vary proportionally depending on a distance apart between the Hall sensor and the magnet when the Hall sensor moves relative to the magnet as the input button is being depressed, so as to serve as a measure of an amount of depression of the input button.

In Example 9, the subject matter of Example 7 or 8 may optionally include a flexible elongated electrical component electrically connecting the Hall sensor to a circuit board of the peripheral input device, wherein the flexible elongated electrical component may run underneath the resting surface of the input button, wherein the touch sensing element may be disposed between the resting surface of the input button and the flexible elongated electrical component, and wherein the flexible elongated electrical component electrically may connect the touch sensing element to the circuit board of the peripheral input device.

In Example 10, the subject matter of any one of Examples 1 to 5 may optionally include that wherein the first interactive part of the displacement sensing arrangement may include a light blocking member having a cut-out profile, the light blocking member being operatively connected to the input button in a manner so as to be capable of being moved by the input button when the input button is being depressed, wherein the second interactive part of the displacement sensing arrangement may include an optical sensing sub-arrangement fixedly disposed in the housing, and wherein the interaction between the first interactive part and the second interactive part may be the optical sensing sub-arrangement detecting a light from the optical sensing sub-arrangement passing through the cut-out profile of the light blocking member during relative movement between the light blocking member and the optical sensing sub-arrangement.

In Example 11, the subject matter of Example 10 may optionally include that wherein the cut-out profile of the light blocking member may have a shape which may proportionally vary an amount of light from the optical sensing sub-arrangement passing therethrough when the light blocking member moves relative to the optical sensing sub-arrangement as the input button is being depressed such that the optical sensing sub-arrangement may be capable of detecting the amount of light as a measure of an amount of depression of the input button.

In Example 12, the subject matter of Example 10 or 11 may optionally include that wherein the optical sensing sub-arrangement may include a light emitter for emitting the light along a light path, a light sensor disposed in the light path and configured to sense the light passing through the cut-out profile of the light blocking member, wherein the light blocking member may move transversely across the light path when the input button is being depressed.

In Example 13, the subject matter of any one of Examples 10 to 12 may optionally include a motion transfer sub-arrangement connected between the input button and the light blocking member, wherein the motion transfer sub-arrangement may transfer a motion of the input button to a corresponding movement of the light blocking member for interacting with the optical sensing sub-arrangement.

In Example 14, the subject matter of Example 13 may optionally include that wherein the input button may be a trigger button pivotable about a pivoting axis relative to the housing, wherein the motion transfer sub-arrangement may include
a V-shaped lever pivotable about a joint between two arms of the V-shaped lever, and
a guide portion at the light blocking member, the guide portion having an inclined slot with respect to a direction of movement of the light blocking member,
wherein a free-end of a first arm of the two arms of the V-shaped lever may be abutting the trigger button and a free-end of a second arm of the two arms of the V-shaped lever may have a pin element slotted into the inclined slot of the guide portion,
wherein depressing the trigger button may cause the V-shaped lever to pivot about the joint between the two arms of the V-shaped lever so as to slide the pin element at the free-end of the second arm of the two arms of the V-shaped lever along the inclined slot of the guide portion at the light blocking member to move the light blocking member relative to the optical sensing sub-arrangement.

In Example 15, the subject matter of Example 14 may optionally include a circuit board; and a torsion spring aligned to the pivoting axis of the trigger button, wherein a first leg of the torsion spring may be connected to the touch sensing element and a second leg of the torsion spring may be connected to the circuit board so as to electrically connect the touch sensing element to the circuit board.

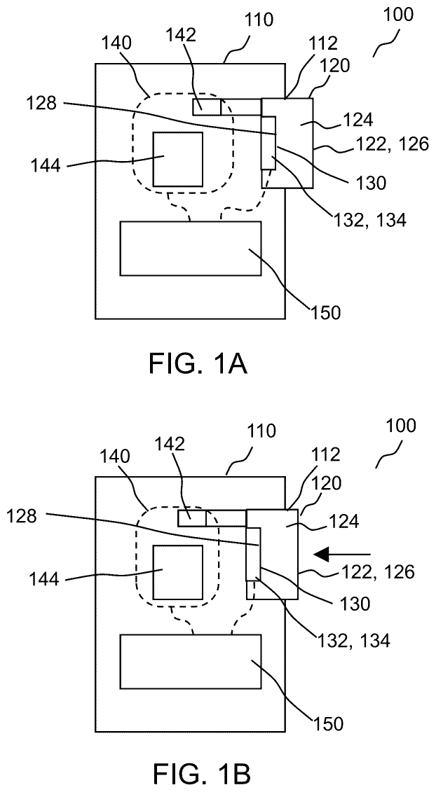

FIG. 1A shows a schematic view of a peripheral input device 100 according to various embodiments. FIG. 1B shows a schematic view of the peripheral input device 100 when at least one input button 120 is depressed according to various embodiments. According to various embodiments, the peripheral input device 100 may be a Virtual Reality (VR) peripheral input device including, but not limited to, a VR controller, a VR glove, a VR body suit, a VR treadmill, a VR track pad, a VR joystick, or a VR motion tracker, whereby the VR peripheral input device may include the at least one input button 120 that may be depressible. According to various embodiments, the at least one input button 120 may be, but not limited to, a push-button which may be pressed or pushed, a trigger which may be pressed or clicked or pulled, a thumb stick which may be pressed or pushed, or the like. According to various embodiments, the peripheral input device 100 may be a handheld device and/or a standalone portable device for providing input to a computing system running a VR application. The peripheral input device may be held or worn or carried by the user. The user may interact with the VR application and/or a virtual world via the peripheral input device. Accordingly, the peripheral input device may be an independent device wieldable or wearable or carriable by the user and may allow the user to provide input to the computing system for interacting with the VR application and/or a virtual world.

According to various embodiments, the peripheral input device 100 may include a housing 110. The housing 110 may be an exterior casing of the peripheral input device 100. Further, the housing 110 may define an inner cavity to house or encase internal components of the peripheral input device 100. The housing 110 may include a grip or a cuff or a handle which may allow the user to hold or wear or carry the peripheral input device 100 while operating the peripheral input device 100 for providing input.

According to various embodiments, the at least one input button 120 may be depressible relative to the housing 110. Accordingly, the at least one input button 120 may be moved relative to the housing 110 when the at least one input button 120 is being pressed or pushed, or clicked or pulled. Further, depressing the at least one input button 120 relative to the housing 110 may include linear or translational type of motion or pivoting type of motion.

According to various embodiments, the at least one input button 120 may include a resting surface 122 for receiving a finger of a user. Accordingly, the user may place the finger on the resting surface 122 of the at least one input button 120 for depressing the at least one input button 120 relative to the housing 110. Hence, the resting surface 122 of the at least one input button 120 may be exposed from the housing 110 of the peripheral input device 100. For example, the housing 110 of the peripheral input device 100 may include an opening 112 through which the resting surface 122 of the at least one input button 120 may be exposed, and the resting surface 122 of the at least one input button 120 may be directed outward and away from the housing 110 through the opening 112 of the housing 110 of the peripheral input device 100.

According to various embodiments, the peripheral input device 100 may include a touch sensing arrangement 130. The touch sensing arrangement 130 may be configured to sense or detect whether the finger of the user is touching (i.e. contacting) or in near proximity to the resting surface 122 of the at least one input button 120. Accordingly, the touch sensing arrangement 130 may enable the at least one input button 120 to detect and sense, whereby the resting surface 122 of the at least one input button 120 may serve as a sensing surface for detecting whether the finger of the user is touching (i.e. contacting) or in near proximity. For example, the touch sensing arrangement 130 may be a capacitive touch sensing arrangement, or an inductive touch sensing arrangement, or a resistive touch sensing arrangement, or an optical touch sensing arrangement.

According to various embodiments, the touch sensing arrangement 130 may include a touch sensing element 132 disposed at the at least one input button 120 to sense a presence of the finger of the user at the resting surface 122 of the at least one input button 120. According to various embodiments, the touch sensing element 132 may detect whether the finger of the user is touching (i. e. in contact) or in near proximity to the resting surface 122 of the at least one input button 120. According to various embodiments, the touch sensing element 132 may detect or sense or measure a change in a force field or energy field at the resting surface 122 of the at least one input button 120 due to an interference caused by the finger of the user touching (i. e. contacting) or be in near proximity to the resting surface 122 of the at least one input button 120. For example, the touch sensing element 132 may detect a change in capacitance when the touch sensing arrangement 130 is the capacitive touch sensing arrangement, or the touch sensing element 132 may detect a change in magnetic field when the touch sensing arrangement 130 is the inductive touch sensing arrangement, or the touch sensing element may detect a change in resistance when the touch sensing arrangement 130 is the resistive touch sensing arrangement, or the touch sensing element may detect a change in light when the touch sensing arrangement 130 is the optical touch sensing arrangement. According to various embodiments, depending on the type of the touch sensing arrangement 130, the touch sensing element 132 may be disposed accordingly at the at least one input button 120 in a manner so as to be capable of performing the type of sensing or detection or measurement required for registering the change in the corresponding force field or energy field at the resting surface 122 of the at least one input button 120 when the finger of the user touches (i. e. contacts) or come into near proximity to the resting surface 122 of the at least one input button 120 to cause the interference.

According to various embodiments, the peripheral input device 100 may include a displacement sensing arrangement 140. The displacement sensing arrangement 140 may be configured to sense or detect whether the at least one input button 120 is depressed or being depressed. For example, the displacement sensing arrangement 140 may include, but not limited to, a switch mechanism or a trigger mechanism or a toggle mechanism. According to various embodiments, the displacement sensing arrangement 140 may include a first interactive part 142 and a second interactive part 144. According to various embodiments, the first interactive part 142 and the second interactive part 144 of the displacement sensing arrangement 140 may be configured such that depressing the at least one input button 120 relative to the housing 110 of the peripheral input device 100 may cause the first interactive part 142 and the second interactive part 144 to interact with each other in a manner capable of being sensed or detected or measured. For example, an interaction between the first interactive part 142 and the second interactive part 144 may be, but not limited to, a mechanical/physical interaction, or an optical interaction, or a magnetic interaction or an electrical interaction. According to various embodiments, the interaction between the first interactive part 142 and the second interactive part 144 may create or generate or produce or cause or result in a change in a stimulus or a property that is capable of being detected or sensed or measured. The stimulus or the property may include, but not limited to, a mechanical/physical stimulus or property, an optical stimulus or property, a magnetic stimulus or property, or an electrical stimulus or property.

According to various embodiments, the first interactive part 142 may be associated with the at least one input button 120 in a manner so as to be movable when the at least one input button 120 is being depressed. Accordingly, the first interactive part 142 may be disposed in operative relation with the at least one input button 120 such that depressing the at least one input button 120 may result in a corresponding movement of the first interactive part 142. For example, the first interactive part 142 may be coupled or connected (directly or indirectly) with the at least one input button 120 such that the first interactive part 142 may move synchronously together with the at least one input button 120 when the at least one input button 120 is being depressed. As another example, the first interactive part 142 may be actuated or moved by the at least one input button 120 whereby depressing the at least one input button 120 may transmit or transfer the motion of depressing the at least one input button 120 to the first interactive part 142 so as to result in the first interactive part 142 being moved.

According to various embodiments, the second interactive part 144 may be disposed in a fixed position with respect to the housing 110. Accordingly, a position of the second interactive part 144 may be fixed in relation to the housing 110. For example, the second interactive part 144 may be fixedly coupled, mounted, attached or connected (directly or indirectly) to the housing 110 in a manner so as to prohibit or disallow relative movement between second interactive part 144 and the housing 110. Hence, the second interactive part 144 may be fixedly disposed or positioned in relation to the housing 110 such that the second interactive part 144 and the housing 110 may be free of relative movement.

According to various embodiments, relative movement between the first interactive part 142 and the second interactive part 144 when the at least one input button 120 is being depressed relative to the housing 110 may cause or result in the interaction between the first interactive part 142 and the second interactive part 144. Accordingly, depressing the at least one input button 120 may move the first interactive part 142 and the second interactive part 144 relative to each other, which may then cause or result in the interaction between the first interactive part 142 and the second interactive part 144. For example, moving the first interactive part 142 and the second interactive part 144 relative to each other, due to the at least one input button 120 being depressed, may cause or result in the mechanical/physical interaction, or the optical interaction, or the magnetic interaction, or the electrical interaction, between the first interactive part 142 and the second interactive part 144. According to various embodiments, the interaction between the first interactive part 142 and the second interactive part 144 may serve as a measure of detecting or sensing that the at least one input button 120 is being depressed. Accordingly, sensing or detecting or measuring the interaction between the first interactive part 142 and the second interactive part 144 may serve as an indication that the at least one input button 120 is being depressed. Hence, a determination of whether the at least one input button 120 is being depressed may be based on sensing or detecting or measuring the interaction between the first interactive part 142 and the second interactive part 144. According to various embodiments, sensing or detecting or measuring the interaction between the first interactive part 142 and the second interactive part 144 may include sensing or detecting or measuring the change in the stimulus or the property due to the interaction between the first interactive part 142 and the second interactive part 144. According to various embodiments, the first interactive part 142 and the second interactive part 144 may be configured to sense or detect or measure the change in the stimulus or the property.

According to various embodiments, with the touch sensing arrangement 130 and the displacement sensing arrangement 140 operatively associated with the (same) at least one input button 120, the at least one input button 120 of the peripheral input device 100 may allow the user to provide at least two different kinds of input using the same input button. According to various embodiments, the at least one input button 120 of the peripheral input device 100 may be operated by touch sensing for providing a first kind of input and may be operated by depressing the at least one input button 120 for providing a second kind of input. Accordingly, the user may operate the at least one input button 120 of the peripheral input device 100 differently, e.g. via touch sensing or depressing, to provide different kinds of input using the peripheral input device 100. For example, the at least one input button 120 of the peripheral input device 100 may be operated, via touch sensing, to simulate grabbing or picking up an object or item in a virtual world, and the (same) at least one input button 120 of the peripheral input device 100 may be further operated, via depressing the at least one input button 120 of the peripheral input device 100, to squeeze, throw, move, pull, push, or swing the same object or item in the virtual world.

According to various embodiments, the touch sensing arrangement 130 and the displacement sensing arrangement 140 may be different and separate sensing arrangements operatively associated with the (same) at least one input button 120. Accordingly, the touch sensing element 132 of the touch sensing arrangement 130 may be distinct and separate from the first interactive part 142 and the second interactive part 144 of the displacement sensing arrangement 140. Hence, a single input button (i.e. the at least one input button 120) may be associated with at least two different and separate sensing arrangements (i.e. the touch sensing arrangement 130 and the displacement sensing arrangement 140) such that the single input button may allow the user to provide at least two different kinds of input using the same single input button.

According to various embodiments, the touch sensing arrangement 130 may output a touch signal upon sensing the presence of the finger of the user at the resting surface 122 of the at least one input button 120 of the peripheral input device 100. Accordingly, when the touch sensing element 132 of the touch sensing arrangement 130 detects or senses or measures the change in the force field or the energy field at the resting surface 122 of the at least one input button 120 due to an interference caused by the finger of the user touching or be in near proximity to the resting surface 122 of the at least one input button 120, the touch sensing arrangement 130 may output the touch signal to indicate that the finger of the user is touching (i.e. contacting) or in near proximity to the resting surface 122 of the at least one input button 120. Hence, the touch signal may serve as the first kind of input to be provided by the operation of the at least one input button 120 of the peripheral input device 100. According to various embodiments, the touch signal may correspond to a detection or a measurement of the change in the force field or the energy field at the resting surface 122 of the at least one input button 120.

According to various embodiments, the the displacement sensing arrangement 140 may output a displacement signal upon detecting that the at least one input button 120 is being depressed by the user. Accordingly, when the at least one input button 120 is being depressed by the user, the first interactive part 142 and the second interactive part 144 of the displacement sensing arrangement 140 may be moved relative to each other causing the interaction between the first interactive part 142 and the second interactive part 144, and the first interactive part 142 and/or the second interactive part 144 may sense or detect or measure the change in the stimulus or the property due to the interaction between the first interactive part 142 and the second interactive part 144 so as to output the displacement signal as an indication that the displacement sensing arrangement 140 has detected the at least one input button 120 is being depressed by the user. For example, the first interactive part 142 or the second interactive part 144 or both may be or include a sensor for sensing or detecting or measuring the change in the stimulus or the property. According to various embodiments, the displacement signal may correspond to a detection or a measurement of the change in the stimulus or the property due to the interaction between the first interactive part 142 and the second interactive part 144.

According to various embodiments, the displacement sensing arrangement 140 may be turned on or activated upon the touch sensing arrangement 130 sensing the presence of the finger of the user at the resting surface 122 of the input button 120. Accordingly, the displacement sensing arrangement 140 may be normally off and may be turned on or activated, for sensing or detecting or measuring the change in the stimulus or the property due to the interaction between the first interactive part 142 and the second interactive part 144 as the measure of detecting the at least one input button 120 is being depressed, after the touch sensing arrangement 130 has detected that the finger of the user is touching (i.e. contacting) or in near proximity to the resting surface 122 of the at least one input button 120. Turning on or activating the displacement sensing arrangement 140 may refer to powering up the displacement sensing arrangement 140 such that the displacement sensing arrangement 140 may be capable of sensing or detecting or measuring the change in the stimulus or the property due to the interaction between the first interactive part 142 and the second interactive part 144. For example, the first interactive part 142 and/or the second interactive part 144 of the displacement sensing arrangement 140 may be turned on or activated after the touch sensing arrangement 130 has determined that the finger of the user is touching (i.e. contacting) or in near proximity to the resting surface 122 of the at least one input button 120 such that the first interactive part 142 and/or the second interactive part 144 of the displacement sensing arrangement 140 may be capable of sensing or detecting or measuring the change in the stimulus or the property due to the interaction between the first interactive part 142 and the second interactive part 144.

According to various embodiments, the displacement sensing arrangement 140 may be turned off or deactivated when the touch sensing arrangement 130 cease to sense the presence of the finger of the user at the resting surface 122 of the input button 120. Accordingly, after the displacement sensing arrangement 140 is powered up for sensing or detecting or measuring, the displacement sensing arrangement 140 may be powered down to return to the normally off state when the touch sensing arrangement 130 has detected that the finger of the user is away or no longer at the resting surface 122 of the input button 120. Turning off or deactivating the displacement sensing arrangement 140 may refer to powering down the displacement sensing arrangement 140 such that the displacement sensing arrangement 140 may no longer sense or detect or measure the change in the stimulus or the property due to the interaction between the first interactive part 142 and the second interactive part 144. For example, the first interactive part 142 and/or the second interactive part 144 of the displacement sensing arrangement 140 may be turned off or deactivated after the touch sensing arrangement 130 has determined that the finger of the user is away or no longer near the resting surface 122 of the at least one input button 120 such that the first interactive part 142 and/or the second interactive part 144 of the displacement sensing arrangement 140 may cease to sense or detect or measure the stimulus or the property.

According to various embodiments, the peripheral input device 100 may include a processor 150. The processor 150 may be electrically connected to the touch sensing arrangement 130 and the displacement sensing arrangement 140. According to various embodiments, the touch sensing element 132 of the touch sensing arrangement 130 may be electrically connected to the processor 150 such that the touch signal may be sent to the processor 150. According to various embodiments, the first interactive part 142 and/or the second interactive part 144 of the displacement sensing arrangement 140 may be electrically connected to the processor 150 such that the displacement signal may be sent to the processor 150.

In various embodiments, the “processor 150” may be understood as any kind of a logic implementing entity, which may be special purpose circuitry or a processor executing software stored in a memory, firmware, or any combination thereof. Thus, in an embodiment, the “processor 150” may be a hard-wired logic circuit or a programmable logic circuit such as a programmable processor, e. g. a microprocessor (e. g. a Complex Instruction Set Computer (CISC) processor or a Reduced Instruction Set Computer (RISC) processor). The “processor 150” may also be a processor executing software, e. g. any kind of computer program, e. g. a computer program using a virtual machine code such as e. g. Java. Any other kind of implementation of the respective functions which are described in more detail throughout may also be understood as the “processor 150” in accordance with various embodiments. In various embodiments, the “processor 150” may be part of a computing system or a controller or a microcontroller or any other system providing a processing capability. According to various embodiments, such systems may include a memory which is for example used in the processing carried out by the device or system. A memory used in the embodiments may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e. g., a floating gate memory, a charge trapping memory, an MRAM (Magneto-resistive Random Access Memory) or a PCRAM (Phase Change Random Access Memory).

According to various embodiments, the processor 150 may be configured to turn on or activate the displacement sensing arrangement 140 upon receiving the touch signal from the touch sensing arrangement 130 indicating that the touch sensing arrangement 130 has sensed or detected the presence of the finger of the user at the resting surface 122 of the at least one input button 120 of the peripheral input device 100. According to various embodiments, the processor 150 may turn on or activate the displacement sensing arrangement 140 by controlling a supply of power to the displacement sensing arrangement 140 or controlling a power source to supply power to the displacement sensing arrangement 140. According to various embodiments, the processor 150 may be configured to turn off or deactivate the displacement sensing arrangement 140 upon receiving the touch signal from the touch sensing arrangement 130 indicating that the touch sensing arrangement 130 has cease to sense or detect the presence of the finger of the user at the resting surface 122 of the at least one input button 120 of the peripheral input device 100. According to various embodiments, the processor 150 may turn off or deactivate the displacement sensing arrangement 140 by cutting the supply of power to the displacement sensing arrangement 140 or controlling the power source to cut the supply of power to the displacement sensing arrangement 140.

According to various embodiments, the input button 120 may include a button cap 124. The button cap 124 may be a cover or a shell giving a physical form and appearance to the input button 120. According to various embodiments, the resting surface 122 of the input button 120 may be a crown surface 126 of the button cap 124. The crown surface 126 of the button cap 124 may be an exterior surface of a roof or a ceiling or a topmost portion of the button cap 124. According to various embodiments, the crown surface 126 of the button cap 124 may be exposed through the housing 110 of the peripheral input device 100. Further, the crown surface 126 of the button cap 124 may be directed outward and away from the housing 110 of the peripheral input device 100.

According to some embodiments, for example as shown in FIG. 1A and FIG. 1B, the touch sensing element 132 of the touch sensing arrangement 130 may be disposed at an underside surface 128 of the button cap 124 opposite the crown surface 126 of the button cap 124. The underside surface 128 and the crown surface 126 may be two opposite surfaces of the button cap 124. For example, the underside surface 128 and the crown surface 126 may be the two opposite surfaces of the roof or the ceiling or the topmost portion of the button cap 124. Accordingly, the underside surface 128 and the crown surface 126 may be directly opposite each other. Further, the touch sensing element 132 of the touch sensing arrangement 130 may be attached or coupled to the underside surface 128 of the button cap 124. Hence, the touch sensing element 132 of the touch sensing arrangement 130 may be disposed at the button cap 124 (i. e. the input button 120) in a manner so as to be directly opposite the crown surface 126 of the button cap 124 (i. e. the resting surface 122 of the input button 120). Thus, the touch sensing element 132 of the touch sensing arrangement 130 may be underneath or under or below the crown surface 126 of the button cap 124 (i. e. the resting surface 122 of the input button 120).

According to some embodiments, when the touch sensing arrangement 130 is the capacitive touch sensing arrangement, the touch sensing element 132 of the touch sensing arrangement 130 may include or may be a conductive metal plate 134. The conductive metal plate 134 may be configured for capacitive sensing.

According to various embodiments, the interaction between the first interactive part 142 and the second interactive part 144 of the displacement sensing arrangement 140 may vary continuously across a range of relative movement between the first interactive part 142 and the second interactive part 144. Accordingly, the interaction between the first interactive part 142 and the second interactive part 144 of the displacement sensing arrangement 140 over the range of relative movement between the first interactive part 142 and the second interactive part 144 may create or generate or produce or cause or result in a continuous gradual change in the stimulus or the property that is to be sensed or measured. Hence, as the first interactive part 142 and the second interactive part 144 moved relative to each other through the range of relative movement, the interaction between the first interactive part 142 and the second interactive part 144 may continuously change or vary in a gradual manner. The continuous gradual change in the interaction between the first interactive part 142 and the second interactive part 144 may proportionally vary or change the stimulus or the property in a similar continuous gradual manner. Thus, sensing or measuring an amount of change or variation in the stimulus or the property may be used to determine a corresponding amount of relative movement between the first interactive part 142 and the second interactive part 144 or a corresponding amount of depression of the at least one input button 120. Accordingly, the continuous change or variation in the interaction between the first interactive part 142 and the second interactive part 144 may be capable of serving as a measurement corresponding to the amount of depression of the at least one input button 120 relative to the housing 110. Therefore, the displacement sensing arrangement 140 may serve as or resemble an analog switch mechanism or analog trigger mechanism capable of providing a range of displacement output corresponding to a range of depression of the at least one input button 120 relative to the housing 110.

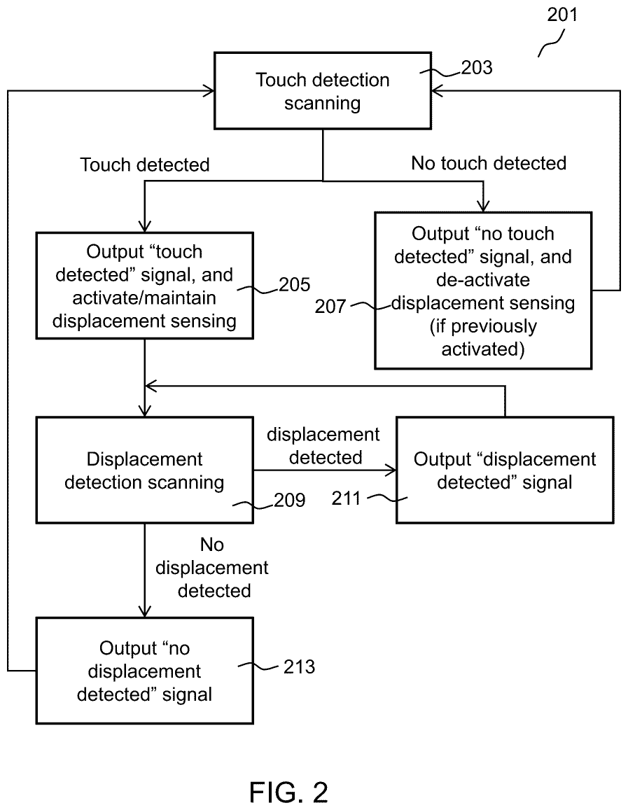

FIG. 2 shows a flow diagram 201 of an operational process of the peripheral input device 100. According to various embodiments, the touch sensing arrangement 130 of the peripheral input device 100 may perform touch detection scanning (for example, see 203). Accordingly, the touch sensing arrangement 130 may be constantly scanning for the presence of the finger of the user at the resting surface 122 of the at least one input button 120. If the presence of the finger of the user at the resting surface 122 of the at least one input button 120 is detected, the touch sensing arrangement 130 may output a “touch detected” signal (for example, see 205). If no presence of the finger of the user at the resting surface 122 of the at least one input button 120 is detected, the touch sensing arrangement 130 may output a “no touch detected” signal (for example, see 207).

When the presence of the finger of the user at the resting surface 122 of the at least one input button 120 is detected, the displacement sensing arrangement 140 of the peripheral input device 100 may be turned on or activated (for example, see 205). The displacement sensing arrangement 140 may be normally off and may be turned on or activated when the touch sensing arrangement 130 output the “touch detected” signal. The “touch detected” signal may be sent from the touch sensing arrangement 130 to the processor 150. The processor 150 may then turn on or activate the displacement sensing arrangement 140.

When the displacement sensing arrangement 140 of the peripheral input device 100 is turned on or activated, the displacement sensing arrangement 140 may perform displacement detection scanning (for example, see 209). Accordingly, the displacement sensing arrangement 140 may be scanning to determine whether the at least one input button 120 has been displaced relative to the housing 110. Further, the displacement sensing arrangement 140 may also be scanning for how much the at least one input button 120 is displaced with respect to the housing 110. If relative movement between the at least one input button 120 and the housing 110 is detected by the displacement sensing arrangement 140, the displacement sensing arrangement 140 may output a “displacement detected” signal (for example, see 211) and looped back to continue displacement scanning at 207. If no displacement is detected by the displacement sensing arrangement 140, the displacement sensing arrangement 140 may output a “no displacement detected” signal (for example, see 213) and the process may be looped back to the touch sensing arrangement 130 for checking whether the finger of the user is still at the resting surface 122 of the at least one input button 120 at 203.

After looping back to the touch sensing arrangement 130, if the presence of the finger of the user at the resting surface 122 of the at least one input button 120 is detected, the touch sensing arrangement 130 may output a “touch detected” signal and the displacement sensing arrangement 140 may be maintained in the turned on or activated mode so as to maintain displacement sensing (for example, see 205). However, If no presence of the finger of the user at the resting surface 122 of the at least one input button 120 is detected after looping back to the touch sensing arrangement 130, the touch sensing arrangement 130 may output a “no touch detected” signal and the displacement sensing arrangement 140 may be deactivated (for example, see 207). The “no touch detected” signal may be sent from the touch sensing arrangement 130 to the processor 150. The processor 150 may then turn off or deactivate the displacement sensing arrangement 140.

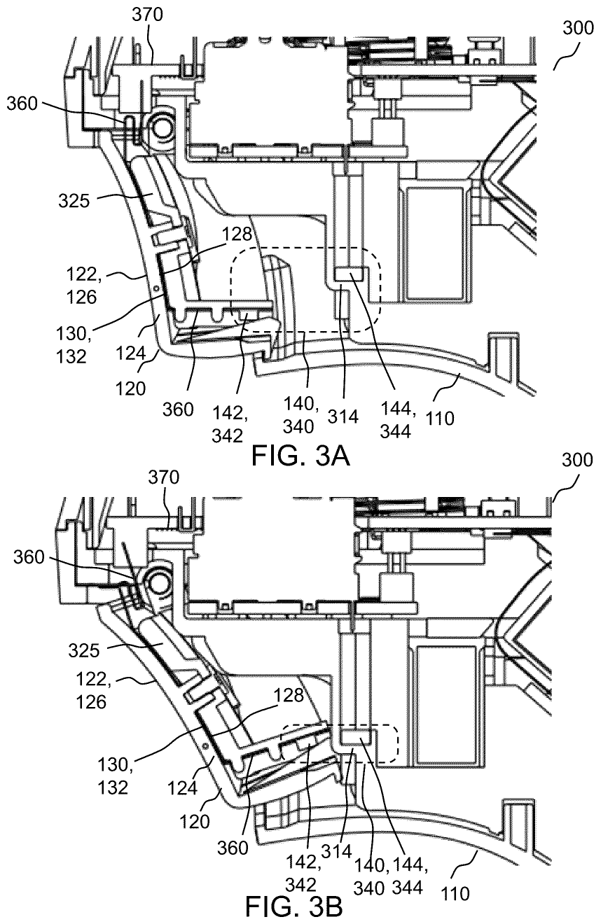

FIG. 3A shows a cross-section of a portion of a peripheral input device 300 according to various embodiments. FIG. 3B shows the cross-section of the portion of the peripheral input device 300 when at least one input button 120 is depressed according to various embodiments. The peripheral input device 300 may be an example embodiment of the peripheral input device 100 of FIG. 1A and FIG. 1B. According to various embodiments, the peripheral input device 300 of FIG. 3A and FIG. 3B includes all the features and limitations of the peripheral input device 100 of FIG. 1A and FIG. 1B. Accordingly, all features, changes, modifications, and variations that are applicable to the peripheral input device 100 of FIG. 1A and FIG. 1B may also be applicable to the peripheral input device 300 of FIG. 3A and FIG. 3B. According to various embodiments, the peripheral input device 300 may include the housing 110, the at least one input button 120 with the resting surface 122, the touch sensing arrangement 130 including the touch sensing element 132, the displacement sensing arrangement 140 having the first interactive part 142 and the second interactive part 144, and/or the processor 150.

In FIG. 3A and FIG. 3B, the peripheral input device 300 (being an example embodiment of the peripheral input device 100 of FIG. 1A and FIG. 1B) is depicted with the displacement sensing arrangement 140 being a Hall-effect displacement sensing arrangement 340. According to various embodiments, in the peripheral input device 300, the displacement sensing arrangement 140 (or the Hall-effect displacement sensing arrangement 340) may include the first interactive part 142 and the second interactive part 144.

The first interactive part 142 may include a Hall sensor 342. The Hall sensor 342 (i. e. the first interactive part 142) may be coupled to the at least one input button 120 in a manner so as to be movable together with the at least one input button 120 when the at least one input button 120 is being depressed. Accordingly, the Hall sensor 342 (i. e. the first interactive part 142) may be coupled or connected (directly or indirectly) with the at least one input button 120 such that the Hall sensor 342 (i. e. the first interactive part 142) may move synchronously together with the at least one input button 120 when the at least one input button 120 is being depressed. Hence, the Hall sensor 342 (i. e. the first interactive part 142) and the at least one input button 120 may be assembled together as a unit movable as a complete whole when the at least one input button 120 is being depressed. The Hall sensor 342 (i. e. the first interactive part 142) and the at least one input button 120 may be free of relative movement therebetween when the at least one input button 120 is being depressed.

The second interactive part 144 may include a magnet 344. The magnet 344 (i. e. the second interactive part 144) may be fixedly disposed in the housing 110. Accordingly, a position of the magnet 344 (i. e. the second interactive part 144) may be fixed in relation to the housing 110. Further, the magnet 344 (i. e. the second interactive part 144) may be disposed in a fixed position with respect to the housing in a manner so as to prohibit or disallow relative movement between the magnet 344 (i. e. the second interactive part 144) and the housing 110. Hence, the magnet 344 (i. e. the second interactive part 144) and the housing 110 may be free of relative movement. As shown in FIG. 3A and FIG. 3B, the magnet 344 may be fixedly coupled to an internal frame 314 or structure of the peripheral input device 300. The internal frame 314 or structure may be fixedly coupled to the housing 110. Thus, fixedly coupling the magnet 344 to the internal frame 314 or structure that is fixed to the housing 110 may fixed a disposition of the magnet 344 relative to the housing 110.

When the first interactive part 142 is the Hall sensor 342 and the second interactive part 144 is the magnet 344, the interaction between the first interactive part 142 and the second interactive part 144 may be the Hall sensor 342 (i. e. the first interactive part 142) detecting or sensing or measuring a magnetic field of the magnet 344 (i.e. the second interactive part) during relative movement between the Hall sensor 342 and the magnet 344 as the at least one input button 120 is being depressed. Hence, the interaction between the first interactive part 142 and the second interactive part 144 may be a magnetic interaction whereby the the Hall sensor 342 (i.e. the first interactive part 142) interacts with the magnetic field of the magnet 344 (i.e. the second interactive part 144) for sensing or detecting or measuring a change in the magnetic field. Accordingly, the magnetic field of the magnet 344 (i.e. the second interactive part 144) may be the stimulus or property that is being sensed or measured by the Hall-effect displacement sensing arrangement 340 (i.e. the displacement sensing arrangement 140).

In the peripheral input device 300, the Hall sensor 342 (i.e. the first interactive part 142) may be moved relative to the magnet 344 (i.e. the second interactive part 144) when the at least one input button 120 is being depressed relative to the housing 110. Accordingly, the Hall sensor 342 (i.e. the first interactive part 142) may be moved towards the magnet 344 (i.e. the second interactive part 144) when the at least one input button 120 is being depressed relative to the housing 110, and the Hall sensor 342 (i.e. the first interactive part 142) may be moved away from the magnet 344 (i.e. the second interactive part 144) when the at least one input button 120 is being released.

Further, the Hall sensor 342 (i.e. the first interactive part 142) may measure an intensity of the magnetic field of the magnet 344 (i.e. the second interactive part 144), which varies proportionally depending on a distance apart between the Hall sensor 342 (i.e. the first interactive part 142) and the magnet 344 (i.e. the second interactive part 144) when the Hall sensor 342 (i.e. the first interactive part 142) moves relative to the magnet 344 (i.e. the second interactive part 144) as the at least one input button 120 is being depressed. The intensity of the magnetic field of the magnet 344 (i.e. the second interactive part 144) decreases with increasing distance away from the magnet 344 (i.e. the second interactive part 144). Accordingly, when the Hall sensor 342 (i.e. the first interactive part 142) moves towards the magnet 344 (i.e. the second interactive part 144) as the at least one input button 120 is being depressed, the intensity of the magnetic field detected or sensed or measured by the Hall sensor 342 (i.e. the first interactive part 142) increases continuously in a gradual manner as the Hall sensor 342 (i.e. the first interactive part 142) moves through a range of distance towards the magnet 344 (i.e. the second interactive part 144). The changes in the intensity of the magnetic field may be proportional to the movement of the Hall sensor 342 (i.e. the first interactive part 142) relative to the magnet 344 (i.e. the second interactive part 144), which corresponds to the amount of depression of the at least one input button 120 of the peripheral input device 300. Therefore, the intensity of the magnetic field detected or sensed or measured may serve as a measure of the amount of depression of the at least one input button 120.

As shown in FIG. 3A and FIG. 3B, the peripheral input device 300 may include a flexible elongated electrical component 360. According to various embodiments, the flexible elongated electrical component 360 may include, but not limited to, a flex cable, a flat cable, a ribbon cable or a flexible printed circuit (FPC). The flexible elongated electrical component 360 may be electrically connected to the Hall sensor 342 (i. e. the first interactive part 142). Further, the peripheral input device 300 may also include a circuit board 370. The processor 150 may be mounted to the circuit board 370. The flexible elongated electrical component 360 may be further electrically connected to the circuit board 370. Accordingly, the flexible elongated electrical component 360 may be electrically connecting the Hall sensor 342 (i. e. the first interactive part 142) to the circuit board 370 so as to connect the Hall sensor 342 (i. e. the first interactive part 142) to the processor 150 on the circuit board 370.

In the peripheral input device 300, the flexible elongated electrical component 360 may run underneath the resting surface 122 of the at least one input button 120 from the Hall sensor 342 (i.e. the first interactive part 142) to the circuit board 370. Accordingly, the flexible elongated electrical component 360 may run across the underside surface 128 of the button cap 124 of the at least one input button 120. As shown, the Hall sensor 342 (i.e. the first interactive part 142) and the circuit board 370 may be on opposite sides of the at least one input button 120. Hence, the the flexible elongated electrical component 360 may be required to run across the the button cap 124 of the at least one input button 120.

According to some embodiments, the touch sensing element 132 of the touch sensing arrangement 130 may be disposed between the resting surface 122 of the at least one input button 120 and the flexible elongated electrical component 360. Accordingly, the touch sensing element 132 of the touch sensing arrangement 130 may be abutting the underside surface 128 of the button cap 124 of the at least one input button 120 and the flexible elongated electrical component 360 may run over the touch sensing element 132 of the touch sensing arrangement 130 such that the touch sensing element 132 of the touch sensing arrangement 130 may be sandwiched between the button cap 124 of the at least one input button 120 and the flexible elongated electrical component 360. Hence, resting surface 122 of the at least one input button 120 and the flexible elongated electrical component 360 may be on two opposite sides of the touch sensing element 132 of the touch sensing arrangement 130.

According to some embodiments, the flexible elongated electrical component 360 may further electrically connects the touch sensing element 132 of the touch sensing arrangement 130 to the circuit board 370. Accordingly, the touch sensing element 132 of the touch sensing arrangement 130 may be electrically connected to the processor 150 on the circuit board 370 via the flexible elongated electrical component 360. Hence, as the flexible elongated electrical component 360 runs across the touch sensing element 132 of the touch sensing arrangement 130 for connecting the Hall sensor 342 (i. e. the first interactive part 142) to the circuit board 370, a portion of the flexible elongated electrical component 360 may be connected to the touch sensing element 132 of the touch sensing arrangement 130 for connecting the touch sensing element 132 to the circuit board 370. By way of example, part of a top surface of the flexible elongated electrical component 360 that abuts the underside surface 128 of the button cap 124 may be coated with electrically conductive material, so as to function as the touch sensing element 132.

As further shown in FIG. 3A and FIG. 3B, the at least one input button 120 may include a button internal frame 325. The button internal frame 325 may be coupled to the button cap 124 to form the at least one input button 120. The Hall sensor 342 (i.e. the first interactive part 142) may be coupled to the button internal frame 325 of the at least one input button 120. As also shown, the Hall sensor 342 (i.e. the first interactive part 142) may be coupled to a portion of the button internal frame 325 away or furthest from the circuit board 370.

Referring to FIG. 3A and FIG. 3B, the button cap 124 and the button internal frame 325 may sandwich or clamp the touch sensing element 132 of the touch sensing arrangement 130 and the flexible elongated electrical component 360 therebetween. Accordingly, by coupling the button cap 124 and the button internal frame 325 together, the button cap 124 and the button internal frame 325 may hold the touch sensing element 132 of the touch sensing arrangement 130 and the flexible elongated electrical component 360 in place.

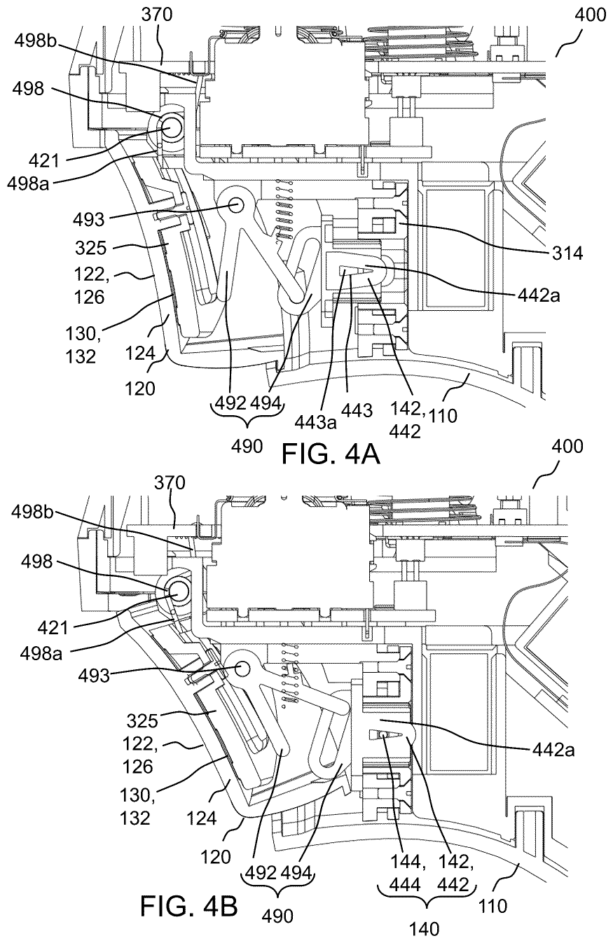

FIG. 4A shows a cross-section of a portion of a peripheral input device 400 according to various embodiments. FIG. 4B shows the cross-section of the portion of the peripheral input device 400 when the at least one input button 120 is depressed according to various embodiments. The peripheral input device 400 may be another example embodiment of the peripheral input device 100 of FIG. 1A and FIG. 1B. According to various embodiments, the peripheral input device 400 of FIG. 4A and FIG. 4B includes all the features and limitations of the peripheral input device 100 of FIG. 1A and FIG. 1B. Accordingly, all features, changes, modifications, and variations that are applicable to the peripheral input device 100 of FIG. 1A and FIG. 1B may also be applicable to the peripheral input device 400 of FIG. 4A and FIG. 4B. According to various embodiments, the peripheral input device 400 may include the housing 110, the at least one input button 120 with the resting surface 122, the touch sensing arrangement 130 including the touch sensing element 132, the displacement sensing arrangement 140 having the first interactive part 142 and the second interactive part 144, and/or the processor 150.

In FIG. 4A and FIG. 4B, the peripheral input device 400 (being an example embodiment of the peripheral input device 100 of FIG. 1A and FIG. 1B) is depicted with the displacement sensing arrangement 140 being an optical displacement sensing arrangement 440. According to various embodiments, in the peripheral input device 400, the displacement sensing arrangement 140 (or the optical displacement sensing arrangement 440) may include the first interactive part 142 and the second interactive part 144.

The first interactive part 142 may include a light blocking member 442. The light blocking member 442 may include a cut-out profile 443. The cut-out profile 443 may define a hole throughwhich light may pass through. Accordingly, the light blocking member 442 may be an opaque piece of structure having the hold defined by the cut-out profile 443, whereby light may pass through the cut-out profile 443 but may be blocked by other portions of the light blocking member 442.

Further, the light blocking member 442 (i. e. the first interactive part 142) may be operatively connected or coupled to the at least one input button 120 in a manner so as to be capable of being moved by the at least one input button 120 when the at least one input button 120 is being depressed. Accordingly, the at least one input button 120 may transmit or transfer the motion of depressing the at least one input button 120 to the light blocking member 442 (i. e. the first interactive part 142) so as to actuate or move the light blocking member 442 (i. e. the first interactive part 142). Hence, the at least one input button 120 may impart a motion to the light blocking member 442 (i. e. the first interactive part 142) for actuating or moving the light blocking member 442 (i. e. the first interactive part 142) when the at least one input button 120 is being depressed relative to the housing 110. However, the light blocking member 442 (i. e. the first interactive part 142) and the at least one input button 120 may not move in the same manner and/or may not be moving in a same type of motion. In other words, depressing the at least one input button 120 relative to the housing 110 may drive the light blocking member 442 (i. e. the first interactive part 142) such that the light blocking member 442 (i. e. the first interactive part 142) may be moved at a same time the at least one input button 120 is being depressed, but the respective motions of the at least one input button 120 and the light blocking member 442 (i. e. the first interactive part 142) may differ.

The second interactive part 144 may include an optical sensing sub-arrangement 444. The optical sensing sub-arrangement 444 (i. e. the second interactive part 144) may be fixedly disposed in the housing 110. Accordingly, a disposition of the optical sensing sub-arrangement 444 (i. e. the second interactive part 144) may be fixed in relation to the housing 110. Further, the optical sensing sub-arrangement 444 (i. e. the second interactive part 144) may be disposed in a fixed disposition with respect to the housing in a manner so as to prohibit or disallow relative movement between the optical sensing sub-arrangement 444 (i. e. the second interactive part 144) and the housing 110. Hence, the optical sensing sub-arrangement 444 (i. e. the second interactive part 144) and the housing 110 may be free of relative movement. As shown in FIG. 4A and FIG. 4B, the optical sensing sub-arrangement 444 may be fixedly coupled to the internal frame 314 or structure of the peripheral input device 400. The internal frame 314 or structure may be fixedly coupled to the housing 110. Thus, fixedly coupling the magnet 344 to the internal frame 314 or structure that is fixed to the housing 110 may fixed a disposition of the optical sensing sub-arrangement 444 relative to the housing 110.

When the first interactive part 142 is the light blocking member 442 and the second interactive part 144 is the optical sensing sub-arrangement 444, the interaction between the first interactive part 142 and the second interactive part 144 may be the the optical sensing sub-arrangement 444 (i. e. the second interactive part 144) detecting or sensing or measuring a light from the optical sensing sub-arrangement 444 (i.e. the second interactive part 144) passing through the cut-out profile 443 of the light blocking member 442 (i.e. the first interactive part 142) during relative movement between the light blocking member 442 and the optical sensing sub-arrangement 444 as the at least one input button 120 is being depressed. Hence, the interaction between the first interactive part 142 and the second interactive part 144 may be an optical interaction whereby the the light blocking member 442 (i.e. the first interactive part 144) interacts with the light from the optical sensing sub-arrangement 444 (i.e. the second interactive part 144) for sensing or detecting or measuring a change in the light. Accordingly, the light from the optical sensing sub-arrangement 444 (i.e. the second interactive part 144) may be the stimulus or property that is being sensed or measured by the optical displacement sensing arrangement 440 (i. e. the displacement sensing arrangement 140).

In the peripheral input device 400, the light blocking member 442 (i.e. the first interactive part 142) may be moved relative to the optical sensing sub-arrangement 444 (i.e. the second interactive part 144) when the at least one input button 120 is being depressed relative to the housing 110. Accordingly, the light blocking member 442 (i.e. the first interactive part 142) may be moved towards the optical sensing sub-arrangement 444 (i.e. the second interactive part 144) when the at least one input button 120 is being depressed relative to the housing 110, and the light blocking member 442 (i.e. the first interactive part 142) may be moved away from the optical sensing sub-arrangement 444 (i.e. the second interactive part 144) when the at least one input button 120 is being released. For example, the light blocking member 442 (i.e. the first interactive part 142) may move transversely across a light path of the light of the optical sensing sub-arrangement 444 (i.e. the second interactive part 144) when the at least one input button 120 is being depressed. In this manner, the cut-out profile 443 may vary the extent of blockage of the light path according to the movement of the light blocking member 442 (i.e. the first interactive part 142) due to the at least one input button 120 being depressed.

Further, the optical sensing sub-arrangement 444 (i.e. the second interactive part 144) may measure an intensity of the light passing through the cut-out profile 443 of the light blocking member 442 (i.e. the first interactive part 142), which may vary proportionally depending on an amount of light passing through the cut-out profile 443 as a degree of overlap between the light blocking member 442 (i.e. the first interactive part 142) and the optical sensing sub-arrangement 444 (i.e. the second interactive part 144) vary when the light blocking member 442 (i.e. the first interactive part 142) moves relative to the optical sensing sub-arrangement 444 (i.e. the second interactive part 144) due to the at least one input button 120 is being depressed. For example, the amount of light passing through the cut-out profile 443 may be dependent on the amount of overlap between the cut-out profile 443 of the light blocking member 442 (i.e. the first interactive part 142) and a light source of the optical sensing sub-arrangement 444 (i.e. the second interactive part 144), which may vary the amount of light passing through the cut-out profile 443.

The intensity of the light passing through the cut-out profile 443 of the light blocking member 442 (i.e. the first interactive part 142) may increase with increasing degree of overlap. Accordingly, when the light blocking member 442 (i.e. the first interactive part 142) moves towards the optical sensing sub-arrangement 444 (i.e. the second interactive part 144) as the at least one input button 120 is being depressed, the intensity of the light detected or sensed or measured by the optical sensing sub-arrangement 444 (i.e. the second interactive part 144) may increases continuously in a gradual manner as the light blocking member 442 (i.e. the first interactive part 142) moves through a range of distance towards the optical sensing sub-arrangement 444 (i.e. the second interactive part 144). The changes in the intensity of the light may be proportional to the movement of the light blocking member 442 (i.e. the first interactive part 142) relative to the optical sensing sub-arrangement 444 (i.e. the second interactive part 144), which corresponds to the amount of depression of the at least one input button 120 of the peripheral input device 400. Therefore, the intensity of the light detected or sensed or measured may serve as a measure of the amount of depression of the at least one input button 120.

For example, the light blocking member 442 (i. e. the first interactive part 142) may include an elongate plate 442a with the cut-out profile 443 and may be disposed so as to move longitudinally to intersect the light path as the at least one input button 120 is being depressed. Further, the cut-out profile 443 may define an elongate shape opening 443a extending from a first longitudinal end portion of the light blocking member 442 (i. e. the first interactive part 142) to a second longitudinal end portion of the light blocking member 442 (i. e. the first interactive part 142). The first longitudinal end portion of the light blocking member 442 (i. e. the first interactive part 142) may be a distal portion situated away from the at least one input button 120, and the second longitudinal end portion of the light blocking member 442 (i. e. the first interactive part 142) may be a proximal portion situated towards the at least one input button 120. The elongate shape opening 443a defined by the cut-out profile 443 may have a width that varies continuously lengthwise. As an example, a width of the elongate shape opening 443a at the first longitudinal end portion of the light blocking member 442 (i. e. the first interactive part 142) may be smaller than a width of the elongate shape opening 443a at the second longitudinal end portion of the light blocking member 442 (i. e. the first interactive part 142). According to various embodiments, the elongate shape opening 443a defined by the cut-out profile 443 may be of a shape including, but not limited to, an inverted triangle shape, a V-shape, or a U-shape.

In the peripheral input device 400, the optical sensing sub-arrangement 444 (i.e. the second interactive part 144) may include a light emitter 480 (for example, see FIG. 6A and FIG. 6B). The light emitter 480 may serve as a light source for emitting the light along the light path. The light emitter 480 may be oriented to emit the light along the light path which may be non-parallel to a motion of the at least one input button 120 as it is being depressed. For example, the light emitter 480 may be oriented such that the light path of the light may be perpendicular to the motion of the at least one input button 120 as it is being depressed. According to various embodiments, the light emitter 480 may include, but not limited to, an infra-red light emitter, a laser light emitter, or a collimated light emitter.

In the peripheral input device 400, the optical sensing sub-arrangement 444 (i.e. the second interactive part 144) may include a light sensor 482 (for example, see FIG. FIG. 6A and FIG. 6B). The light sensor 482 may be disposed in the light path of the light emitted from the light emitter 480. Further, the light sensor 482 may be configured to sense or detect or measure the light passing through the cut-out profile 443 of the light blocking member 442 (i.e. the first interactive part 142) from the light emitter 480. Accordingly, the the light sensor 482 may be placed in a position that is directly facing the light emitter 480. Hence, the light emitter 480 and the light sensor 482 may be arranged in an opposing manner such that the light from the light emitter 480 is directly projected straight towards the light sensor 482. According to various embodiments, the light sensor 482 may sense or detect light incident on the light sensor 482 and output a signal. According to various embodiments, the light sensor 482 may also sense or detect or measure an intensity of light incident on the light sensor 482 and output an analog signal according to the intensity of light detected. According to various embodiments, the light sensor 482 may include, but not limited to, a phototransistor-type light sensor or a photoresistor-type light sensor or a photodiode-type light sensor. In the various embodiments, the light blocking member 442 (i.e. the first interactive part 142) may move transversely across the light path of the light emitted from the light emitter 480 towards the light sensor 482 when the at least one input button 120 is being depressed.

Referring to FIG. 4A and FIG. 4B, the peripheral input device 400 may include a motion transfer sub-arrangement 490. The motion transfer sub-arrangement 490 may be connected between the at least one input button 120 and the light blocking member 442 (i.e. the first interactive part 142). For example, the motion transfer sub-arrangement 490 may operatively connects the at least one input button 120 and the light blocking member 442 (i.e. the first interactive part 142). Accordingly, the motion transfer sub-arrangement 490 may transfer a motion of the at least one input button 120 to a corresponding movement of the light blocking member 442 (i.e. the first interactive part 142) for interacting with the optical sensing sub-arrangement 444 (i.e. the second interactive part 144). Accordingly, the motion of depressing the at least one input button 120 may be transmitted or transferred to the light blocking member 442 (i.e. the first interactive part 142) via the motion transfer sub-arrangement 490 for actuating or moving the light blocking member 442 (i.e. the first interactive part 142). Hence, the motion transfer sub-arrangement 490 may impart the motion of depressing the at least one input button 120 to the light blocking member 442 (i.e. the first interactive part 142) for actuating or moving the light blocking member 442 (i.e. the first interactive part 142) when the at least one input button 120 is being depressed relative to the housing 110.

As shown in FIG. 4A and FIG. 4B, in the peripheral input device 400, the at least one input button 120 may be a trigger button 420. The trigger button 420 (i.e. the at least one input button 120) may be pivotable about a pivoting axis 421 relative to the housing 110. The trigger button 420 (i.e. the at least one input button 120) may be operatively connected to the light blocking member 442 (i.e. the first interactive part 142) via the motion transfer sub-arrangement 490.

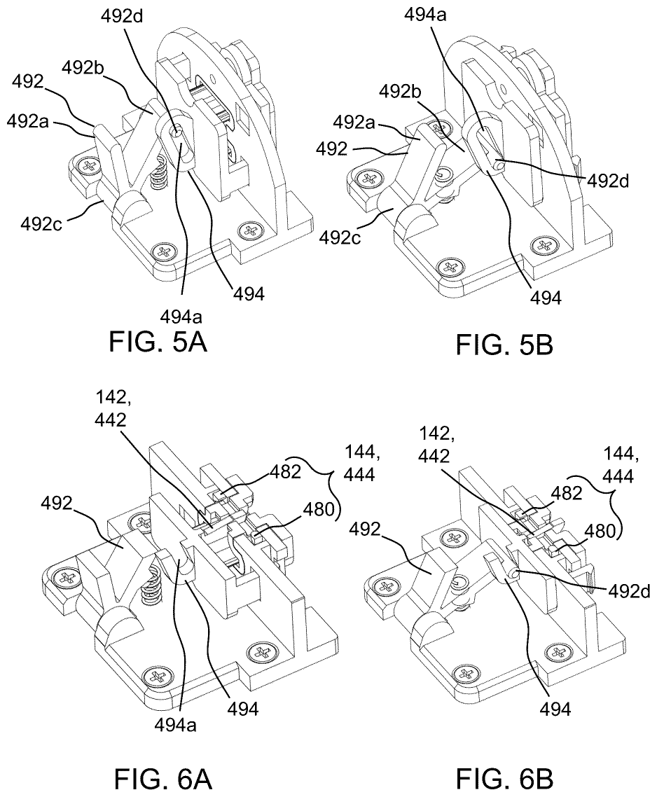

As shown in FIG. 5A and FIG. 5B, in the peripheral input device 400, the motion transfer sub-arrangement 490 may include a V-shaped lever 492. The V-shaped lever 492 may include two arms 492a, 492b and a joint 492c connecting the two arms 492a, 492b. Further the V-shaped lever 492 may be pivotable about the joint 492c between the two arms 492a, 492b of the V-shaped lever 492. A lever pivoting axis 493 of the V-shaped lever 492 may be parallel to the pivoting axis 421 of the trigger button 420 (i.e. the at least one input button 120).

In the peripheral input device 400, the motion transfer sub-arrangement 490 may also include a guide portion 494 at the light blocking member 442 (i.e. the first interactive part 142). The guide portion 494 may be a part of the light blocking member 442 (i.e. the first interactive part 142) or may be integrally attached or coupled or connected to the light blocking member 442 (i.e. the first interactive part 142). The guide portion 494 may include an inclined slot 494a with respect to a direction of movement of the light blocking member 442 (i.e. the first interactive part 142). Accordingly, the inclined slot 494a of the guide portion 494 may form a non-parallel and non-perpendicular angle with the direction of movement of the light blocking member 442 (i.e. the first interactive part 142). When the light blocking member 442 (i.e. the first interactive part 142) includes the elongate plate 442a having the elongate shape opening 443a (i.e. cut-out profile 443) extending longitudinally, the inclined slot 494a of the guide portion 494 may be angled off a longitudinal axis of the elongate plate 442a. Further, the guide portion 494 may be at the second longitudinal end portion of the light blocking member 442 (i.e. the first interactive part 142) proximal to the trigger button 420 (i.e. the at least one input button 120).

As shown in FIG. 4A to 4B and FIG. 5A to 5B, a free-end of a first arm 492a of the two arms of the V-shaped lever 492 may be abutting the trigger button 420 (i.e. the at least one input button 120) and a free-end of a second arm 492b of the two arms of the V-shaped lever 492 may have a pin element 492d slotted into the inclined slot 494a of the guide portion 494. When the trigger button 420 (i.e. the at least one input button 120) is being depressed, the trigger button 420 (i.e. the at least one input button 120) may push against the free-end of the first arm 492a of the two arms of the V-shaped lever 492 causing the V-shaped lever 492 to pivot about the about the joint 492c between the two arms 492a, 492b of the V-shaped lever 492. As the V-shaped lever 492 pivots, the pin element 492d at the free-end of the second arm 492b of the two arms of the V-shaped lever 492 may slide along the inclined slot 494a of the guide portion 494 at the light blocking member 442 (i.e. the first interactive part 142). Sliding the pin element 492d at the free-end of the second arm 492b of the two arms of the V-shaped lever 492 may then move the light blocking member 442 (i.e. the first interactive part 142) relative to the optical sensing sub-arrangement 444 (i.e. the second interactive part 144) for interaction. For example, the light blocking member 442 (i.e. the first interactive part 142) may be moved transversely to intersect the light path of the light of the optical sensing sub-arrangement 444 (i.e. the second interactive part 144) such that the light blocking member 442 (i.e. the first interactive part 142) interacts with the light from the optical sensing sub-arrangement 444 (i.e. the second interactive part 144).

FIG. 5A and FIG. 5B show a sequence of movements of the motion transfer sub-arrangement 490 and the light blocking member 442 (i. e. the first interactive part 142) of the peripheral input device 400 of FIG. 4A and FIG. 4B according to various embodiments. FIG. 6A and FIG. 6B show cut away views of FIG. 5A and FIG. 5B to further illustrate the interaction between the light blocking member 442 (i. e. the first interactive part 142) and the optical sensing sub-arrangement 444 (i. e. the second interactive part 144) of the peripheral input device 400 of FIG. 4A and FIG. 4B according to various embodiments. As shown, the V-shaped lever 492 may be pivoted to slide the pin element 492d at the free-end of the second arm 492b of the two arms of the V-shaped lever 492 along the inclined slot 494a of the guide portion 494 at the light blocking member 442 (i. e. the first interactive part 142) so as to cause the light blocking member 442 (i. e. the first interactive part 142) to move in a direction perpendicular to the lever pivoting axis 493 of the V-shaped lever 492 for interacting with the optical sensing sub-arrangement 444 (i. e. the second interactive part 144). Accordingly, the motion transfer sub-arrangement 490 may transfer or transmit a motion to the light blocking member 442 (i. e. the first interactive part 142) for moving the light blocking member 442 (i. e. the first interactive part 142), whereby the movement of the motion transfer sub-arrangement 490 and the motion of the light blocking member 442 (i. e. the first interactive part 142) may be different types of motions.

Referring back to FIG. 4A and FIG. 4B, the peripheral input device 400 may, similar to the peripheral input device 300 of FIG. 3A and FIG. 3B, include the circuit board 370. Further, the peripheral input device 400 may include a torsion spring 498. The torsion spring 498 may be aligned to the pivoting axis 421 of the trigger button 420 (i. e. the at least one input button 120). Accordingly, the torsion spring 498 may bias the trigger button 420 (i. e. the at least one input button 120) such that the trigger button 420 (i. e. the at least one input button 120) may return to an undepressed state after a force depressing the trigger button 420 (i. e. the at least one input button 120) is removed. In the peripheral input device 400, a first leg 498a of the torsion spring 498 may connected to the touch sensing element 132 of the touch sensing arrangement 130, and a second leg 498b of the torsion spring 498 may be connected to the circuit board 370 so as to electrically connect the touch sensing element 132 to the circuit board 370. Further, the processor 150 may be mounted to the circuit board 370. Accordingly, the torsion spring 498 may electrically connect the the touch sensing element 132 of the touch sensing arrangement 130 to the circuit board 370 so as to connect the the touch sensing element 132 of the touch sensing arrangement 130 to the processor 150 on the circuit board 370.

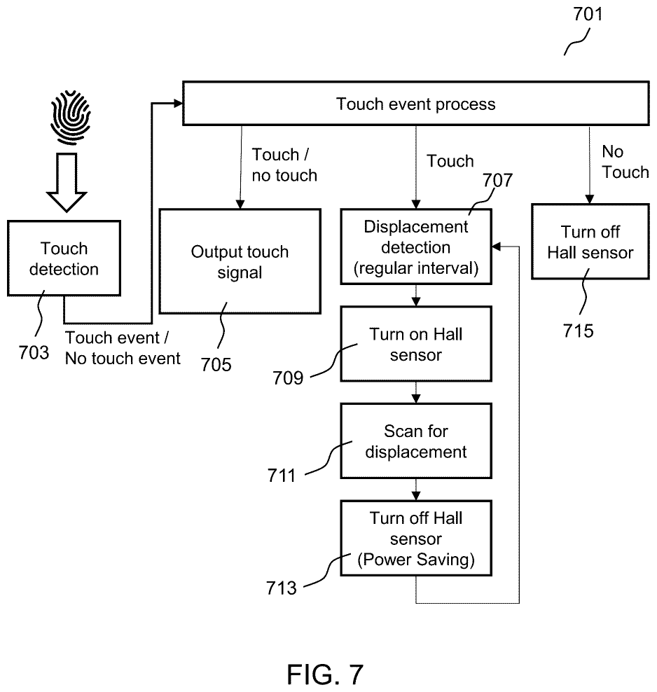

FIG. 7 shows a flow diagram 701 of an operational process of the peripheral input device 300 of FIG. 3A and FIG. 3B. The touch sensing arrangement 130 of the peripheral input device 300 may perform touch detection (for example, see 703) to determine whether there is a “touch event” or a “no touch event”. Based on the types of touch event detected, the peripheral input device 300 may proceed with the following touch event processes. The touch event processes may include a process wherein the touch sensing arrangement 130 of the peripheral input device 300 may output a touch signal (for example, see 705) regardless of whether there is a “touch event” or a “no touch event”. Accordingly, the touch signal that is being output may either be a “touch detected” signal or a “no touch detected” signal.

Further, when there is a “touch event”, the touch event processes may proceed with a process for displacement detection (for example, see 707). The process for displacement detection may be conducted at regular interval. During each cycle of the process for displacement detection, the Hall sensor 342 of the displacement sensing arrangement 140 of the peripheral input device 300 may be turned on or activated (for example, see 709). The Hall sensor 342 of the displacement sensing arrangement 140 may be normally off and may be turned on or activated during each cycle of the process for displacement detection. When the Hall sensor 342 of the displacement sensing arrangement 140 of the peripheral input device 300 is turned on or activated, the displacement sensing arrangement 140 may scan for displacement (for example, see 711). Accordingly, the Hall sensor 342 of the displacement sensing arrangement 140 may be scanning to determine whether the at least one input button 120 has been displaced relative to the housing 110. Further, the Hall sensor 342 of the displacement sensing arrangement 140 may also be scanning for how much the at least one input button 120 is displaced with respect to the housing 110. The Hall sensor 342 of the displacement sensing arrangement 140 may then output a corresponding displacement signal as part of the process. Subsequently, at the end of the cycle of the process for displacement detection, the Hall sensor 342 of the displacement sensing arrangement 140 may be deactivated or turned off such that the displacement sensing arrangement 140 may be in a power saving mode (for example, see 713).

On the other hand, when there is a “no touch event”, the touch event processes may proceed with a process for turning off or deactivating the Hall sensor 342 of the displacement sensing arrangement 140 (for example, see 715). When the Hall sensor 342 of the displacement sensing arrangement 140 is previously turned on, upon detecting a “no touch event” by the touch sensing arrangement 130 of the peripheral input device 300, the process for turning off or deactivating the Hall sensor 342 of the displacement sensing arrangement 140 at 715 may interrupt the touch event processes to turn off or deactivate the Hall sensor 342 of the displacement sensing arrangement 140.

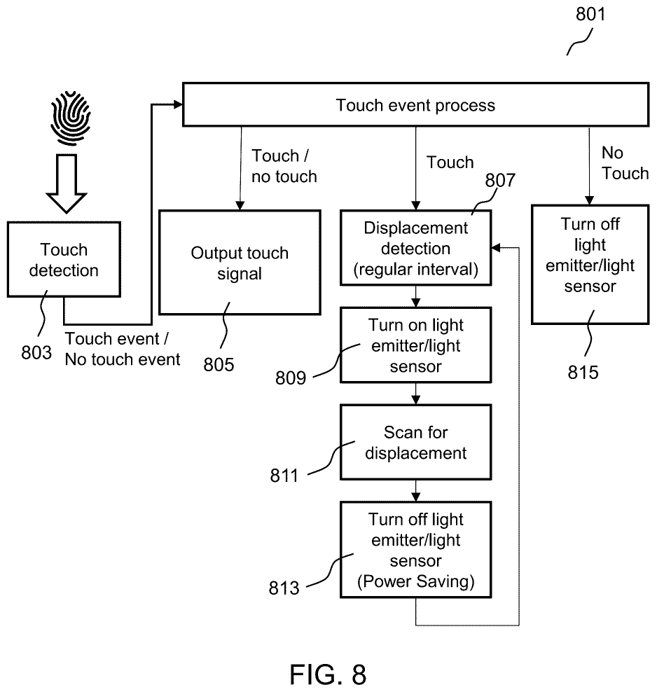

FIG. 8 shows a flow diagram 801 of an operational process of the peripheral input device 400 of FIG. 4A and FIG. 4B. The touch sensing arrangement 130 of the peripheral input device 400 may perform touch detection (for example, see 803) to determine whether there is a “touch event” or a “no touch event”. Based on the types of touch event detected, the peripheral input device 400 may proceed with the following touch event processes. The touch event processes may include a process wherein the touch sensing arrangement 130 of the peripheral input device 400 may output a touch signal (for example, see 805) regardless of whether there is a “touch event” or a “no touch event”. Accordingly, the touch signal that is being output may either be a “touch detected” signal or a “no touch detected” signal.

Further, when there is a “touch event”, the touch event processes may proceed with a process for displacement detection (for example, see 807). The process for displacement detection may be conducted at regular interval. During each cycle of the process for displacement detection, the the light emitter 480 and the light sensor 482 of the displacement sensing arrangement 140 of the peripheral input device 400 may be turned on or activated (for example, see 809). The the light emitter 480 and the light sensor 482 of the displacement sensing arrangement 140 may be normally off and may be turned on or activated during each cycle of the process for displacement detection. When the the light emitter 480 and the light sensor 482 of the displacement sensing arrangement 140 of the peripheral input device 400 are turned on or activated, the displacement sensing arrangement 140 may scan for displacement (for example, see 811). Accordingly, the the light emitter 480 and the light sensor 482 of the displacement sensing arrangement 140 may be scanning to determine whether the at least one input button 120 has been displaced relative to the housing 110. Further, the the light emitter 480 and the light sensor 482 of the displacement sensing arrangement 140 may also be scanning for how much the at least one input button 120 is displaced with respect to the housing 110. The the light emitter 480 and the light sensor 482 of the displacement sensing arrangement 140 may then output a corresponding displacement signal as part of the process. Subsequently, at the end of the cycle of the process for displacement detection, the the light emitter 480 and the light sensor 482 of the displacement sensing arrangement 140 may be deactivated or turned off such that the displacement sensing arrangement 140 may be in a power saving mode (for example, see 813).

On the other hand, when there is a “no touch event”, the touch event processes may proceed with a process for turning off or deactivating the the light emitter 480 and the light sensor 482 of the displacement sensing arrangement 140 (for example, see 815). When the the light emitter 480 and the light sensor 482 of the displacement sensing arrangement 140 are previously turned on, upon detecting a “no touch event” by the touch sensing arrangement 130 of the peripheral input device 400, the process for turning off or deactivating the the light emitter 480 and the light sensor 482 of the displacement sensing arrangement 140 at 815 may interrupt the touch event processes to turn off or deactivate the the light emitter 480 and the light sensor 482 of the displacement sensing arrangement 140.

Various embodiments have provided a peripheral input device having at least one input button capable of allowing the user to provide at least two different kinds of input using the same input button. Accordingly, various embodiments have provided a peripheral input device suitable for use with VR applications whereby the user may reliably and effectively provide different kinds of inputs using the same input button of the peripheral input device.

While the invention has been particularly shown and described with reference to specific embodiments, it should be understood by those skilled in the art that various changes, modification, variation in form and detail may be made therein without departing from the scope of the invention as defined by the appended claims. The scope of the invention is thus indicated by the appended claims and all changes which come within the meaning and range of equivalency of the claims are therefore intended to be embraced.

1. A peripheral input device comprising:
a housing;
an input button depressible relative to the housing, the input button having a resting surface for receiving a finger of a user;
a touch sensing arrangement comprising a touch sensing element disposed at the input button to sense a presence of the finger of the user at the resting surface of the input button; and
a displacement sensing arrangement comprising a first interactive part associated with the input button in a manner so as to be movable when the input button is being depressed, and
a second interactive part disposed in a fixed position with respect to the housing,
wherein relative movement between the first interactive part and the second interactive part when the input button is being depressed causes an interaction between the first interactive part and the second interactive part as a measure of detecting that the input button is being depressed.

2. The peripheral input device as claimed in claim 1,
wherein the touch sensing arrangement outputs a touch signal upon sensing the presence of the finger of the user at the resting surface of the input button,
wherein the displacement sensing arrangement outputs a displacement signal upon detecting that the input button is being depressed.

3. The peripheral input device as claimed in claim 1,
wherein the displacement sensing arrangement is turned on upon the touch sensing arrangement sensing the presence of the finger of the user at the resting surface of the input button, and
wherein the displacement sensing arrangement is turned off when the touch sensing arrangement cease to sense the presence of the finger of the user at the resting surface of the input button.

4. The peripheral input device as claimed in claim 1, wherein the input button comprises a button cap, wherein the resting surface of the input button is a crown surface of the button cap, wherein the touch sensing element of the touch sensing arrangement is disposed at an underside surface of the button cap opposite the crown surface of the button cap.

5. The peripheral input device as claimed in claim 1, wherein the touch sensing element comprises a conductive metal plate.

6. The peripheral input device as claimed in claim 1, wherein the interaction between the first interactive part and the second interactive part of the displacement sensing arrangement varies continuously across a range of relative movement between the first interactive part and the second interactive part in a manner so as to be capable of serving as a measurement corresponding to an amount of depression of the input button.

7. The peripheral input device as claimed in claim 1,
wherein the first interactive part of the displacement sensing arrangement comprises a Hall sensor coupled to the input button in a manner so as to be movable together with the input button when the input button is being depressed,
wherein the second interactive part of the displacement sensing arrangement comprises a magnet fixedly disposed in the housing, and
wherein the interaction between the first interactive part and the second interactive part is the Hall sensor detecting a magnetic field of the magnet during relative movement between the Hall sensor and the magnet.

8. The peripheral input device as claimed in claim 7, wherein the Hall sensor measures an intensity of the magnetic field of the magnet, which varies proportionally depending on a distance apart between the Hall sensor and the magnet when the Hall sensor moves relative to the magnet as the input button is being depressed, so as to serve as a measure of an amount of depression of the input button.

9. The peripheral input device as claimed in claim 7, further comprising a flexible elongated electrical component electrically connecting the Hall sensor to a circuit board of the peripheral input device,
wherein the flexible elongated electrical component runs underneath the resting surface of the input button,
wherein the touch sensing element is disposed between the resting surface of the input button and the flexible elongated electrical component, and
wherein the flexible elongated electrical component electrically connects the touch sensing element to the circuit board of the peripheral input device.

10. The peripheral input device as claimed in claim 1,
wherein the first interactive part of the displacement sensing arrangement comprises a light blocking member having a cut-out profile, the light blocking member being operatively connected to the input button in a manner so as to be capable of being moved by the input button when the input button is being depressed,
wherein the second interactive part of the displacement sensing arrangement comprises an optical sensing sub-arrangement fixedly disposed in the housing, and
wherein the interaction between the first interactive part and the second interactive part is the optical sensing sub-arrangement detecting a light from the optical sensing sub-arrangement passing through the cut-out profile of the light blocking member during relative movement between the light blocking member and the optical sensing sub-arrangement.

11. The peripheral input device as claimed in claim 10, wherein the cut-out profile of the light blocking member has a shape which proportionally varies an amount of light from the optical sensing sub-arrangement passing therethrough when the light blocking member moves relative to the optical sensing sub-arrangement as the input button is being depressed such that the optical sensing sub-arrangement is capable of detecting the amount of light as a measure of an amount of depression of the input button.

12. The peripheral input device as claimed in claim 10, wherein the optical sensing sub-arrangement comprises
a light emitter for emitting the light along a light path,
a light sensor disposed in the light path and configured to sense the light passing through the cut-out profile of the light blocking member,
wherein the light blocking member moves transversely across the light path when the input button is being depressed.

13. The peripheral input device as claimed in claim 10, further comprising a motion transfer sub-arrangement connected between the input button and the light blocking member, wherein the motion transfer sub-arrangement transfer a motion of the input button to a corresponding movement of the light blocking member for interacting with the optical sensing sub-arrangement.

14. The peripheral input device as claimed in claim 13,
wherein the input button is a trigger button pivotable about a pivoting axis relative to the housing,
wherein the motion transfer sub-arrangement comprises a V-shaped lever pivotable about a joint between two arms of the V-shaped lever, and
a guide portion at the light blocking member, the guide portion having an inclined slot with respect to a direction of movement of the light blocking member,
wherein a free-end of a first arm of the two arms of the V-shaped lever is abutting the trigger button and a free-end of a second arm of the two arms of the V-shaped lever has a pin element slotted into the inclined slot of the guide portion,
wherein depressing the trigger button causes the V-shaped lever to pivot about the joint between the two arms of the V-shaped lever so as to slide the pin element at the free-end of the second arm of the two arms of the V-shaped lever along the inclined slot of the guide portion at the light blocking member to move the light blocking member relative to the optical sensing sub-arrangement.

15. The peripheral input device as claimed in claim 14, further comprising
a circuit board; and
a torsion spring aligned to the pivoting axis of the trigger button,
wherein a first leg of the torsion spring is connected to the touch sensing element and a second leg of the torsion spring is connected to the circuit board so as to electrically connect the touch sensing element to the circuit board.
